(19) United States
(12) Patent Application Publication
(10) Pub. No.: US 2014/0299264 A1
(43) Pub. Date: Oct. 9, 2014

(54) SOLUTION OF AROMATIC POLYAMIDE FOR PRODUCING DISPLAY ELEMENT, OPTICAL ELEMENT, OR ILLUMINATION ELEMENT

(71) Applicant: SUMITOMO BAKELITE CO., LTD., Shinagawa-ku (JP)

(72) Inventors: Hideo UMEDA, Kobe-shi (JP); Ritsuya KAWASAKI, Kobe-shi (JP); Jun OKADA, Kobe-shi (JP); Mizuho INOUE, Kobe-shi (JP); Manabu NAITO, Kobe-shi (JP)

(73) Assignee: SUMITOMO BAKELITE CO., LTD., Shinagawa-ku (JP)

(21) Appl. No.: 14/245,272

(22) Filed: Apr. 4, 2014

Related U.S. Application Data
(60) Provisional application No. 61/808,792, filed on Apr. 5, 2013.

(51) Int. Cl. B32B 27/34; B32B 37/14; H01L 51/52; G02B 1/04; G02F 1/1333

(52) U.S. Cl. CPC B32B 27/34; G02B 1/04; G02F 1/1333; H01L 51/52; B32B 37/144; B32B 2307/412; B32B 2315/08; B32B 2377/00; B32B 2457/20; B32B 2551/00
USPC 156/247; 524/606; 524/315; 428/435; 428/337; 428/339; 156/60

(57) ABSTRACT

This disclosure, in one aspect, relates to a solution of polyamide including an aromatic polyamide and an amphiphilic solvent. This disclosure, in another aspect, relates to a solution of polyamide including an aromatic polyamide, an amphiphilic solvent, and an aprotic solvent. This disclosure, in another aspect, relates to a solution of aromatic polyamide for producing a display element, an optical element or an illumination element.

### CROSS REFERENCE TO RELATED APPLICATIONS

This disclosure is based upon and claims priorities from U.S. Provisional Application Ser. No. 61/808,792, the disclosure of which are hereby incorporated by reference herein in its entirety.

### TECHNICAL FIELD

This disclosure, in one aspect, relates to a solution of polyamide including an aromatic polyamide and an amphiphilic solvent for producing a display element, an optical element or an illumination element. This disclosure, in another aspect, relates to a laminated composite material including a glass plate and a polyamide resin layer, wherein the polyamide resin layer is laminated onto one surface of the glass plate, and the polyamide resin layer is obtained by applying the solution of polyamide onto the glass plate. This disclosure, in another aspect, relates to a process for manufacturing a display element, an optical element or an illumination element, including the step of forming a polyamide film using the solution of polyamide.

### BACKGROUND ART

As transparency is required of display elements, glass substrates using a glass plate have been used as substrates for the elements (JP10311987 (A)). However, for display elements using a glass substrate, problems such as being heavy in weight, breakable and unbendable have been pointed out at times. Thus, the use of a transparent resin film instead of a glass substrate has been proposed.

For example, polycarbonates, which have high transparency, are known as transparent resins for use in optical applications. However, their heat resistance and mechanical strength can be an issue when using them in manufacturing display elements. On the other hand, examples of heat resistant resins include polyimides. However, typical polyimides are brown-colored, and it can be an issue for use in optical applications. As polyimides with transparency, those having a ring structure are known. However, the problem with such polyimides is that they have poor heat resistance.

For polyamide films for use in optical applications, WO 2004/039863 and JP 2008260266(A) each disclose an aromatic polyamide having a diamine including a trifluoro group, which provides both high stiffness and heat resistance.

WO 2012/129422 discloses a transparent polyamide film with thermal stability and dimension stability. This transparent film is manufactured by casting a solution of aromatic polyamide and curing the casted solution at a high temperature. The document discloses that the cured film has a transmittance of more than 80% over a range of 400 to 750 nm, a coefficient of thermal expansion (CTE) of less than 20 ppm/° C., and shows favorable solvent resistance. And the document discloses that the film can be used as a flexible substrate for a microelectronic device.

### SUMMARY

This disclosure, in one aspect, relates to a solution of polyamide including an aromatic polyamide and an amphiphilic solvent.

This disclosure, in another aspect, relates to a laminated composite material including a glass plate and a polyamide resin layer, wherein the polyamide resin layer is laminated onto one surface of the glass plate, and the polyamide resin layer is obtained by applying the solution of polyamide onto the glass plate.

Further, this disclosure, in another aspect, relates to a process for manufacturing a display element, an optical element or an illumination element, including the step of forming the display element, the optical element or the illumination element on a surface of the polyamide resin layer of the laminated composite material, wherein the surface is not opposed to the glass plate. Further, this disclosure, in another aspect, relates to a display element, an optical element or an illumination element manufactured through the process.

### BRIEF DESCRIPTION OF THE DRAWINGS

FIG. 1 is a schematic cross-sectional view showing a configuration of an organic EL element 1 according to one embodiment.

FIG. 2 is a flow chart for explaining a process for manufacturing an OLED element according to one embodiment.

### DETAILED DESCRIPTION

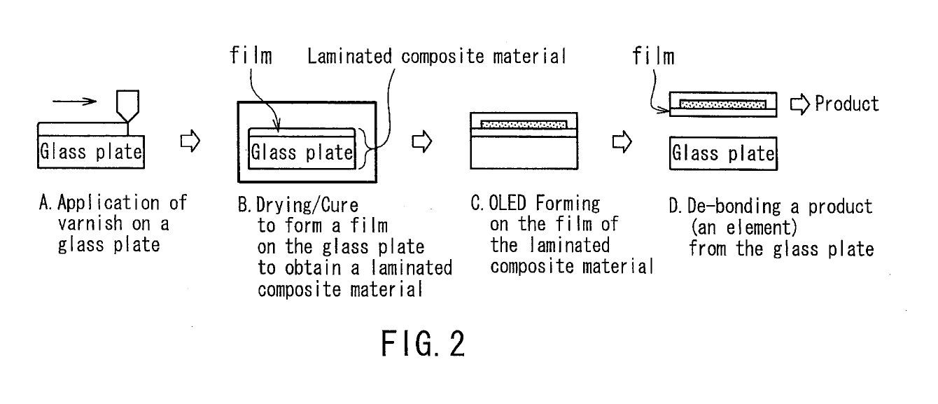

A display element, an optical element, or an illumination element such as an organic electro-luminescence (OEL) or organic light-emitting diode (OLED) is often produced by the process described in FIG. 2. Briefly, a polymer solution (varnish) is applied or casted onto a glass base or a silicon wafer base (step A), the applied polymer solution is cured to form a film (step B), an element such as OLED is formed on the film (step C), and then, the element such as OLED (product) is de-bonded from the base (step D). These days, polyimide film is used as the film in the process in FIG. 2.

It is known that the use of a solvent with a high polarity, such as an amide-based solvent, in polyamideimide varnish results in whitening of a coating of the varnish (WO 2012/144563). Further, when a solvent with a high polarity, such as an amide-based solvent, is used in polyamide varnish in a process for manufacturing a display element, an optical element, or an illumination element, such as the one described in FIG. 2, the following problem occurs. That is, if the varnish (solution of polyamide) applied onto a glass base is set aside after the step A, the varnish becomes white before the drying and/or curing step (Step B). The whiting of the varnish is not preferred because it may become a cause of, for example, a decline in transparency and deterioration of the surface smoothness of a film obtained from the varnish. With these problems, it was found that the use of an amphiphilic solvent as a solvent of the varnish allowed an extension of time for the varnish to become white. That is, it was found that when the solution of polyamide contained an amphiphilic solvent, the whitening of the solution after being applied onto a glass base was able to be suppressed. It was also found that the use of an aprotic solvent in combination with an amphiphilic solvent as a solvent of the solution of polyamide allowed even further suppression of the whitening and improvements in efficiency and obtainability of the polyamide solution, whereby improving the efficiency of manufacturing a laminate composite material, a display element, an optical element, or an illumination element.

Therefore, this disclosure, in one or plurality of embodiments, relates to a solution of polyamide including an aromatic polyamide and an amphiphilic solvent. Further, in one or plurality of embodiments, this disclosure relates to a solution of polyamide including an aromatic polyamide, an amphiphilic solvent and an aprotic solvent. Furthermore, in one or plurality of embodiments, this disclosure relates to a solution of polyamide that can be prevented from becoming white.

[Amphiphilic Solvent]

As to why the inclusion of an amphiphilic solvent results in suppression of the whitening of applied varnish, the detailed mechanism is not clear but it is assumed as follows. That is, even if the solution of polyamide according to this disclosure is applied and absorbs water, a decline in solubility of the polyamide in the amphiphilic solvent is suppressed, so that the precipitation of the polyamide, i.e., the whitening can be suppressed. However, this disclosure may not be interpreted based solely on such a mechanism.

In one or plurality of embodiments, in terms of suppressing the whitening, examples of the amphiphilic solvent used in the solution of polyamide according to this disclosure include an amphiphilic solvent composed of a hydrocarbon group, and a hydroxyl group and/or an ether linkage. In one or plurality of embodiments, examples of the amphiphilic solvent include an ether-based solvent, a glycol-based solvent, a glycol ester-based solvent or a combination thereof, or an ether-based solvent, a glycol ester-based solvent or a combination thereof or an ether-based solvent. In one or plurality of embodiments, examples of ether-based solvents include butyl cellosolve, methyl cellosolve, ethyl cellosolve, and a combination thereof, or butyl cellosolve. In one or plurality of embodiments, examples of glycol-based solvents include ethylene glycol and diethylene glycol. Examples of glycol ester-based solvents include ethylenglycol monobuthylether, propylene glycol monobuthylether, diethyleneglycol monobuthylether, and a combination thereof.

[Aprotic Solvent]

As to why the inclusion of an aprotic solvent in combination with an amphiphilic solvent results in suppression of the whitening of applied varnish, the detailed mechanism is not clear but it is assumed as follows. In some cases, the solubility of polyamide in an amphiphilic solvent may not be high, and such solubility may become a cause of the precipitation of polyamide (whitening). On the other hand, an aprotic solvent can dissolve polyamide favorably but a decline in solubility due to water absorption may lead to the precipitation of polyamide. Therefore, by combining amphiphilic and aprotic solvents, it is believed that both an improvement in solubility of polyamide and suppression of decline in solubility due to water absorption can be achieved at the same time, thereby achieving favorable suppression of the whitening. It should be noted that this disclosure may not be interpreted based solely on such a mechanism.

Examples of the aprotic solvent used in the solution of polyamide according to this disclosure include: sulfoxide-based solvents such as dimethyl sulfoxide and diethyl sulfoxide; formamide-based solvents such as N,N-dimethylformamide and N,N-diethylformamide; acetamide-based solvents such as N,N-dimethylacetamide and N,N-diethylacetamide; pyrrolidone-based solvents such as N-methyl-2-pyrrolidone and N-vinyl-2-pyrrolidone; phenol-based solvents such as phenol, o-, m- or p-cresol, xylenol, halogenated phenol and catechol; hexamethylphosphoramide; and γ-butyrolactone. In particular, in terms of improving the capability of dissolving polyamide and suppressing the whitening, the aprotic solvent may be, in one or plurality of embodiments, one having a nitrogen atom. In one or plurality of embodiments, the aprotic solvent is N,N-dimethylacetamide (DMAc), DMSO, N-methyl-2-pyrrolidone (NMP), N-dimethylformamide (DMF) or a combination thereof. In one or plurality of embodiments, the aprotic solvent is DMAc or NMP. In one or plurality of embodiments, the aprotic solvent is DMAc.

In one or plurality of embodiments, in terms of improving the capability of dissolving polyamide and suppressing the whitening, the mixed weight ratio between the amphiphilic solvent and the aprotic solvent is 5:95 to 95:5, 10:90 to 90:10, or 20:80 to 80:20.

[Polyimide]

In one or plurality of embodiments, in terms of using a film in a display element, an optical element, or an illumination element and suppressing the whitening, the polyamide of the solution of polyamide according to this disclosure may be an aromatic polyamide having repeat units represented by the following general formulas (I) and (II).

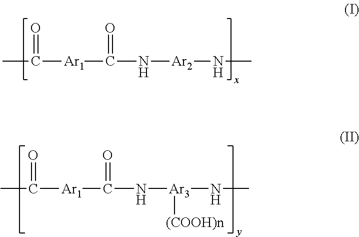

wherein x represents mole % of the repeat structure (I), y represents mole % of the repeat structure (II), x varies from 90 to 100, and y varies from 10 to 0;

wherein n=1 to 4;

wherein Ar₁ is selected from the group comprising:

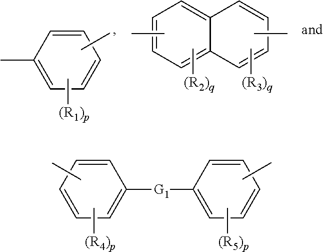

wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, or substituted aryl such as halogenated aryls, alkyl ester and substituted alkyl esters, and combinations thereof. It is to be understood that each R₁ can be different, each R₂ can be different, each R₃ can be different, each R₄ can be different, and each R₅ can be different. G₁ is selected from a group comprising a covalent bond; a CH₂ group; a C(CH₃)₂ group; a C(CF₃)₂ group; a C(CX₃)₂ group, wherein X is a halogen (fluoride, chloride, bromide, and iodide); a CO group; an O atom; a S atom; a SO₂ group; a Si (CH₃)₂ group; 9,9-fluorene group; substituted 9,9-fluorene; and an OZO group, wherein Z is an aryl group or substituted aryl group, such as phenyl group, biphenyl group, perfluorobiphenyl group, 9,9-bisphenylfluorene group, and substituted 9,9-bisphenylfluorene;

wherein Ar₂ is selected from the group of comprising:

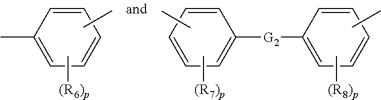

wherein p=4, wherein R₆, R₇, R₈ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof. It is to be understood that each R₆ can be different, each R₇ can be different, and each R₈ can be different. G₂ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is an aryl group or substituted aryl group, such as phenyl group, biphenyl group, perfluorobiphenyl group, 9,9-bisphenylfluorene group, and substituted 9,9-bisphenylfluorene;

wherein Ar₃ is selected from the group comprising:

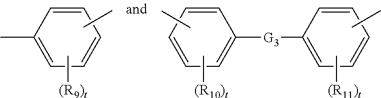

wherein t=1 to 3, wherein R₉, R₁₀, R₁₁ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof. It is to be understood that each R₉ can be different, each R₁₀ can be different, and each R₁₁ can be different. G₃ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is an aryl group or substituted aryl group, such as phenyl group, biphenyl group, perfluorobiphenyl group, 9,9-bisphenylfluorene group, and substituted 9,9-bisphenylfluorene.

In one or plurality of embodiments of this disclosure, (I) and (II) are selected so that the polyamide is soluble in a polar solvent or a mixed solvent comprising one or more polar solvents. In one or plurality of embodiments of this disclosure, x varies from 90 to 100 mole % of the repeat structure (I), and y varies from 10 to 0 mole % of the repeat structure (II). In one or plurality of embodiments of this disclosure, the aromatic polyamide contains multiple repeat units with the structures (I) and (II) where Ar₁, Ar₂, and Ar₃ are the same or different.

In one or plurality of embodiments, in terms of using a film in a display element, an optical element, or an illumination element and suppressing the whitening, the solution of polyamide according to this disclosure is one obtained or may be obtained through a manufacturing process including the following steps. However, the solution of polyamide according to this disclosure is not limited to the one manufactured through the following manufacturing process.

a) dissolving at least one aromatic diamine in a solvent;

b) reacting the at least one aromatic diamine mixture with at least one aromatic diacid dichloride, wherein hydrochloric acid and a polyamide solution is generated; and

c) removing the free hydrochloric acid by reaction with a trapping reagent;

In one or more embodiments of the process for manufacturing a polyamide solution of this disclosure, the aromatic diacid dichloride includes those shown in the following general structures:

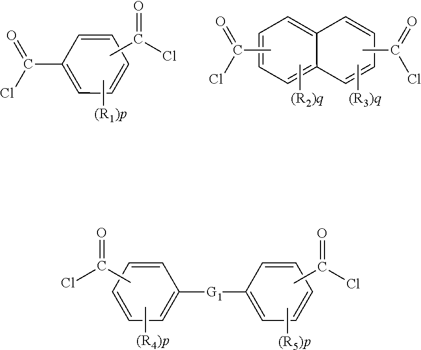

wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as a halogenated alkoxy, aryl, or substituted aryl such as halogenated aryls, alkyl ester and substituted alkyl esters, and combinations thereof. It is to be understood that each R₁ can be different, each R₂ can be different, each R₃ can be different, each R₄ can be different, and each R₅ can be different. G₁ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is an aryl group or substituted aryl group, such as phenyl group, biphenyl group, perfluorobiphenyl group, 9,9-bisphenylfluorene group, and substituted 9,9-bisphenylfluorene.

In one or plurality of embodiments, in terms of using a film in a display element, an optical element, or an illumination element and suppressing the whitening, examples of the aromatic dicarboxylic acid dichloride used in the process for manufacturing a solution of polyamide according to this disclosure include the following.

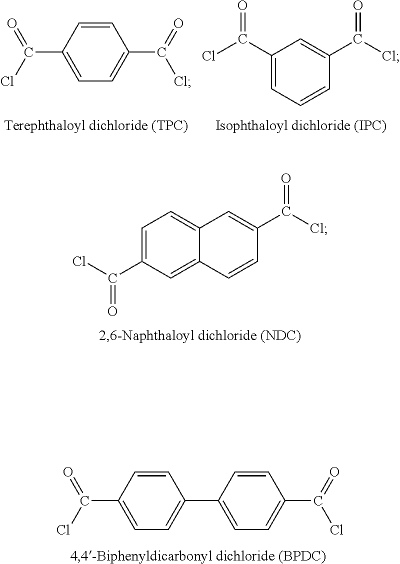

In one or more embodiments of the process for manufacturing a polyamide solution of this disclosure, the aromatic diamine includes those shown in the following general structures:

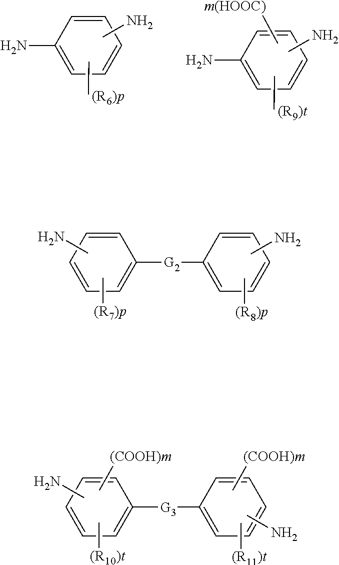

wherein p=4, m=1 or 2, and t=1 to 3, wherein R₆, R₇, R₈, R₉, R₁₀, R₁₁ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as a halogenated alkoxy, aryl, substituted aryl such as halogenated aryls, alkyl ester, and substituted alkyl esters, and combinations thereof. It is to be understood that each R₆ can be different, each R₇ can be different, each R₈ can be different, each R₉ can be different, each R₁₀ can be different, and each R₁₁ can be different. G₂ and G₃ are selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is an aryl group or substituted aryl group, such as phenyl group, biphenyl group, perfluorobiphenyl group, 9,9-bisphenylfluorene group, and substituted 9,9-bisphenylfluorene.

In one or plurality of embodiments, in terms of using a film in a display element, an optical element, or an illumination element and suppressing the whitening, examples of the aromatic diamine used in the process for manufacturing a solution of polyamide according to this disclosure include the following.

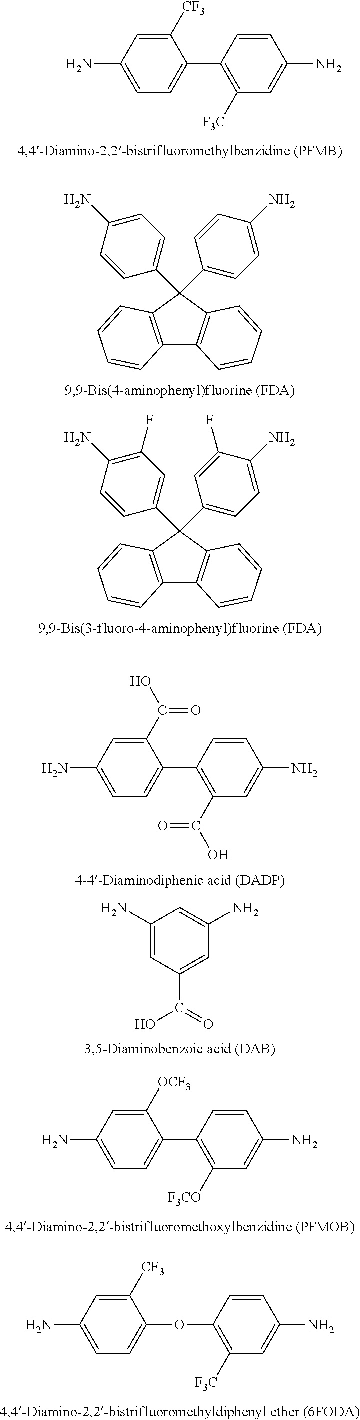

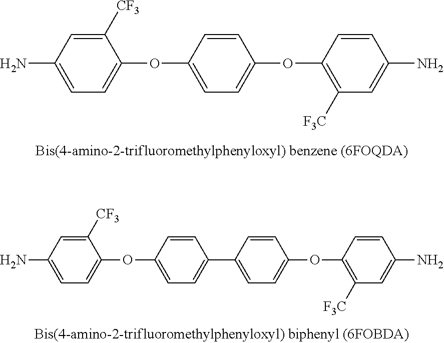 [SMILES: Nc1ccc(Oc2ccc(Oc3ccc(N)cc3C(F)(F)F)cc2)c(C(F)(F)F)c1 ; Nc1ccc(Oc2ccc(-c3ccc(Oc4ccc(N)cc4C(F)(F)F)cc3)cc2)c(C(F)(F)F)c1]

In one or more embodiments of the process for manufacturing a polyamide solution of this disclosure, a polyamide is prepared via a condensation polymerization in a solvent, where the hydrochloric acid generated in the reaction is trapped by a reagent like propylene oxide (PrO).

In one or plurality of embodiments of this disclosure, in terms of use of the polyamide solution in the process for manufacturing a display element, an optical element or an illumination element, the reaction of hydrochloric acid with the trapping reagent yields a volatile product.

In one or plurality of embodiments of this disclosure, in terms of use of the polyamide solution in the process for manufacturing a display element, an optical element or an illumination element, the trapping reagent is propylene oxide (PrO). In one or plurality of embodiments of this disclosure, the trapping reagent is added to the mixture before or during the reacting step (b). Adding the reagent before or during the reaction step (b) can reduce degree of viscosity and generation of lumps in the mixture after the reaction step (b), and therefore, can improve productivity of the solution of the polyamide. These effects are significant specifically when the reagent is organic reagent, such as propylene oxide.

In one or plurality of embodiments of this disclosure, in terms of enhancement of heat resistance property of the polyamide film, the process further comprises the step of end-capping of one or both of terminal —COOH group and terminal —NH₂ group of the polyamide. The terminal of the polyamide can be end-capped by the reaction of polymerized polyamide with benzoyl chloride when the terminal of Polyamide is —NH₂, or reaction of polymerized PA with aniline when the terminal of Polyamide is —COOH. However, the method of end-capping is not limited to this method.

In one or plurality of embodiments of this disclosure, in terms of use of the polyamide solution in the process for manufacturing a display element, an optical element or an illumination element, the polyamide is first isolated from the polyamide solution by precipitation and redissolved in a solvent. The precipitation can be carried out by a typical method. In one or plurality of embodiments, by adding the polyamide to methanol, ethanol, isopropyl alcohol or the like, it is precipitated, cleaned, and dissolved in the solvent, for example.

In one or plurality of embodiments of this disclosure, in terms of use of the polyamide solution in the process for manufacturing a display element, an optical element or an illumination element, the solution is produced in the absence of inorganic salt.

[Flexible Backbone of Polyamide]

In one or plurality of embodiments, in terms of using a film in a display element, an optical element, or an illumination element and suppressing the whitening, the aromatic polyamide of the solution of polyamide according to this disclosure has a flexible backbone. In one or plurality of embodiments, the term “the aromatic polyamide having a flexible backbone” as used herein means that an aromatic group in the polyamide main chain has repeat units that are bonded to a position other than the para-position, or refers to polyamide synthesized using aromatic monomer components having a flexible backbone. Therefore, it can be said that an aromatic diamine monomer component having a flexible backbone is an aromatic diamine monomer component in which two amino groups are bonded to a bivalent aromatic group (arylene group) at o- or m-position or an aromatic diamine monomer component in which two amino groups are bonded to a bivalent aromatic group (arylene group) at a position other than p-position. Similarly, it can be said that an aromatic dicarboxylic acid dichloride monomer component having a flexible backbone is an aromatic dicarboxylic acid dichloride monomer component in which two —COCl groups are bonded to a bivalent aromatic group (arylene group) at o- or m-position or an aromatic dicarboxylic acid dichloride monomer component in which two —COCl groups are bonded to a bivalent aromatic group (arylene group) at a position other than p-position.

In one or plurality of embodiments, in terms of using a film in a display element, an optical element, or an illumination element, the ratio of an amount of flexible monomers to a total amount of monomers used for synthesis of the aromatic polyamide of the solution of polyamide according to this disclosure is 10.0 mol % or more, 15.0 mol % or more, more than 15.0 mol %, 17.5 mol % or more, more than 17.5 mol %, or 20.0 mol % or more. Further, in one or plurality of embodiments, in terms of using a film in a display element, an optical element, or an illumination element and suppressing thermal expansion of the film, the ratio of an amount of flexible monomers to a total amount of monomers used for synthesis of the aromatic polyamide of the solution of polyamide according to this disclosure is 90.0 mol % or less, 80.0 mol % or less, 70.0 mol % or less, 60.0 mol % or less, or 50.0 mol % or less.

In one or plurality of embodiments, in terms of using a film in a display element, an optical element, or an illumination element and suppressing the whitening, the ratio of an amount of aromatic diamine monomer components that have an arylene group other than para bond to a total amount of diamine monomer components used for synthesis of the aromatic polyamide of the solution of polyamide according to this disclosure is 15 mol % or more, 20 mol % or more, 30 mol % or more, or 35 mol % or more.

In one or plurality of embodiments, in terms of using a film in a display element, an optical element, or an illumination element and suppressing the whitening, the ratio of an amount of aromatic dicarboxylic acid dichloride monomer components that have an arylene group other than para bond to a total amount of dicarboxylic acid dichloride monomer components used for synthesis of the aromatic polyamide of the solution of polyamide according to this disclosure is 20 mol % or more, 25 mol % or more, or 30 mol % or more.

[Average Molecular Weight of Polyamide]

In one or plurality of embodiments, in terms of using a film in a display element, an optical element, or an illumination element and suppressing the whitening, it is preferable that the aromatic polyamide of the solution of polyamide according to this disclosure has a number-average molecular weight (Mn) of 6.0×10⁴ or more, 6.5×10⁴ or more, 7.0×10⁴ or more, 7.5×10⁴ or more, or 8.0×10⁴ or more. Similarly, in one or plurality of embodiments, the number-average molecular weight is 1.0×10⁶ or less, 8.0×10⁵ or less, 6.0×10⁵ or less, or 4.0×10⁵ or less.

In this disclosure, the number-average molecular weight (Mn) and the weight-average molecular weight (Mw) of the polyamide are measured by Gel Permeation Chromatography, and more specifically, they are measured by a method described in Examples.

In one or plurality of embodiments, in terms of using a film in a display element, an optical element, or an illumination element and suppressing the whitening, it is preferable that the molecular weight distribution (=Mw/Mn) of the aromatic polyamide of the solution of polyamide according to this disclosure is 5.0 or less, 4.0 or less, 3.0 or less, 2.8 or less, 2.6 or less, or 2.4 or less. Similarly, in one or plurality of embodiments, the molecular weight distribution of the aromatic polyamide is 2.0 or more.

In one or plurality of embodiments, in terms of using a film in a display element, an optical element, or an illumination element, the solution of polyamide according to this disclosure is one undergone re-precipitation after the synthesis of the polyamide.

In one or plurality of embodiments of this disclosure, one or both of terminal —COOH group and terminal —NH₂ group of the aromatic polyamide are end-capped. The end-capping of the terminal is preferable from the point of enhancement of heat resistance property of the polyamide film. The terminal of the polyamide can be end-capped by the reaction of polymerized polyamide with benzoyl chloride when the terminal of Polyamide is —NH₂, or reaction of polymerized PA with aniline when the terminal of Polyamide is —COOH. However, the method of end-capping is not limited to this method.

In one or plurality of embodiments, in terms of using a film in a display element, an optical element, or an illumination element, monomers used for the synthesis of the polyamide of the solution of polyamide according to this disclosure may include a carboxylic group-containing diamine monomer. In that case, the carboxylic group-containing diamine monomer component accounts for, in one or plurality of embodiments, 30 mol % or less, 20 mol % or less, or 1 to 10 mol % of a total amount of monomers.

[Polyamide Content]

In one or plurality of embodiments, in terms of using a film in a display element, an optical element, or an illumination element and suppressing the whitening, the aromatic polyamide content of the solution of polyamide according to this disclosure is 2 wt % or more, 3 wt % or more, or 5 wt % or more. Similarly the aromatic polyamide content is 30 wt % or less, 20 wt % or less, or 15 wt % or less.

[Whitening Time]

In one or plurality of embodiments, the whitening time of the solution of polyamide according this disclosure is 30 minutes or more, 1 hour or more, 2 hours or more, 5 hours or more, 6 hours or more or 24 hours or more. The term “whitening time” as used herein refers to time for the solution of polyamide or polyamide varnish to become white after being applied onto a glass substrate. Here, specific conditions under which the whitening time is observed may be, but are not necessarily limited to, those described in Examples.

In one or plurality of embodiments, the solution of polyamide according to this disclosure is a solution of polyamide for use in a process for manufacturing a display element, an optical element, or an illumination element, including the steps a) to c).

a) applying a solution of an aromatic polyamide onto a base;

b) forming a polyamide film on the base after the applying step (a); and

c) forming the display element, the optical element or the illumination element on the surface of polyamide film,

wherein the base or the surface of the base is composed of glass or silicon wafer.

[Laminated Composite Material]

The term “laminated composite material” as used herein refers to a material in which a glass plate and a polyamide resin layer are laminated. In one or plurality of non-limiting embodiments, a glass plate and a polyamide resin layer being laminated means that the glass plate and the polyamide resin layer are laminated directly. Alternatively, in one or plurality of non-limiting embodiments, it means that the glass plate and the polyamide resin layer are laminated through one or more layers. Herein, the organic resin of the organic resin layer is a polyamide resin. Thus, in one or plurality of embodiments, the laminated composite material of this disclosure includes a glass plate and a polyamide resin layer, and the polyamide resin is laminated on one surface of the glass plate.

In one or plurality of non-limiting embodiments, the laminated composite material according to this disclosure can be used in a process for manufacturing a display element, an optical element or an illumination element, such as the one described in FIG. 2. Further, in one or plurality of none-limiting embodiments, the laminated composite material according to this disclosure can be used as a laminated composite material obtained by the step B of the manufacturing process described in FIG. 2. Therefore, in one or plurality of none-limiting embodiments, the laminated composite material according to this disclosure is a laminated composite material for use in a process for manufacturing a display element, an optical element, or an illumination element, including the step of forming the display element, the optical element, or the illumination element on a surface of the polyamide resin layer, wherein the surface is not opposed to a glass plate.

The laminated composite material according to this disclosure may include additional organic resin layers and/or inorganic layers in addition to the polyamide resin layer. In one or plurality of none-limiting embodiments, examples of additional organic resin layers include a flattening coat layer.

Further, in one or plurality of none-limiting embodiments, examples of inorganic layers include a gas barrier layer capable of suppressing permeation of water, oxygen, or the like and a buffer coat layer capable of suppressing migration of ions to a TFT element.

[Polyamide Resin Layer]

The polyamide resin of the polyamide resin layer of the laminated composite material according to this disclosure is formed using the solution of polyamide according to this disclosure.

In one or plurality of embodiments, in terms of using a film in a display element, an optical element or an illumination element, the polyamide resin has a glass transition temperature of 250 to 550° C., and preferably 300 to 500° C. Note that the glass transition temperature of the polyamide film is measured through dynamic mechanical analysis, and more specifically, it is measured by a method described in Examples.

[Thickness of Polyamide Resin Layer]

In one or plurality of embodiments, in terms of using a film in a display element, an optical element, or an illumination element and suppressing the development of cracks in the resin layer, the polyamide resin layer of the laminated composite material according to this disclosure has a thickness of 500 μm or less, 200 μm or less, or 100 μm or less. Further, in one or plurality of none-limiting embodiments, the polyamide resin layer has a thickness of 1 μm or more, 2 μm or more, or 3 μm or more, for example.

[Transmittance of Polyamide Resin Layer]

In one or plurality of embodiments, the polyamide resin layer of the laminated composite material according to this disclosure has a total light transmittance of 70% or more, 75% or more, or 80% or more in terms of allowing the laminated composite material to be used suitably in the production of a display element, an optical element, or an illumination element.

[Glass Plate]

In one or plurality of embodiments, the material of the glass plate of the laminated composite material according to this disclosure may be, for example, soda-lime glass, none-alkali glass or the like in terms of using a film in a display element, an optical element, or an illumination element.

In terms of using a film in a display element, an optical element, or an illumination element, the glass plate of the laminated composite material according this disclosure has a thickness of 0.3 mm or more, 0.4 mm or more, or 0.5 mm or more. Further, in one or plurality of embodiments, the glass plate has a thickness of 3 mm or less or 1 mm or less, for example.

[Manufacturing Process of Laminated Composite Material]

The laminated composite material according to this disclosure can be manufactured by applying the solution of polyamide according to this disclosure onto a glass plate, drying the applied solution, and if necessary, curing the applied solution.

In one or plurality of embodiments of this disclosure, a process for manufacturing the laminated composite material of this disclosure includes the steps of:

a) applying a solution of an aromatic polyamide onto a base; and

b) heating the casted polyamide solution to form a polyamide film after the applying step (a).

In one or plurality of embodiments of this disclosure, in terms of suppression of curvature deformation and/or enhancement of dimension stability, the heating is carried out under the temperature ranging from approximately +40° C. of the boiling point of the solvent to approximately +100° C. of the boiling point of the solvent, preferably from approximately +60° C. of the boiling point of the solvent to approximately +80° C. of the boiling point of the solvent, more preferably approximately +70° C. of the boiling point of the solvent. In one or plurality of embodiments of this disclosure, in terms of suppression of curvature deformation and/or enhancement of dimension stability, the temperature of the heating in step (b) is between approximately 200° C. and approximately 250° C. In one or plurality of embodiments of this disclosure, in terms of suppression of curvature deformation and/or enhancement of dimension stability, the time of the heating is more than approximately 1 minute and less than approximately 30 minutes.

The process for manufacturing the laminated composite material may include, following the step (b), a curing step (c) in which the polyamide film is cured. The curing temperature depends upon the capability of a heating device but is 220° C. to 420° C., 280 to 400° C., or 330° C. to 370° C. in one or plurality of embodiments.

[Process for manufacturing Display Element, Optical Element or Illumination Element]

This disclosure, in one aspect, relates to a process for manufacturing a display element, an optical element, or an illumination element, which includes the step of forming the display element, the optical element or the illumination element on a surface of the organic resin layer of the laminated composite material of this disclosure, wherein the surface is not opposed to the glass plate. In one or plurality of embodiments, the manufacturing process further includes the step of de-bonding the display element, the optical element, or the illumination element formed from the glass plate.

[Display Element, Optical Element, or Illumination Element]

The term “a display element, an optical element, or an illumination element” as used herein refers to an element that constitutes a display (display device), an optical device, or an illumination device, and examples of such elements include an organic EL element, a liquid crystal element, and organic EL illumination. Further, the term also covers a component of such elements, such as a thin film transistor (TFT) element, a color filter element or the like. In one or more embodiments, the display element, the optical element or the illumination element according to the present disclosure may include the polyamide film according to the present disclosure, may be produced using the solution of polyamide according to the present disclosure, or may use the polyamide film according to the present disclosure as the substrate of the display element, the optical element or the illumination element.

<Non-Limiting Embodiment of Organic EL Element>

Hereinafter, one embodiment of an organic EL element as one embodiment of the display element according to the present disclosure will be described with reference to the drawing.

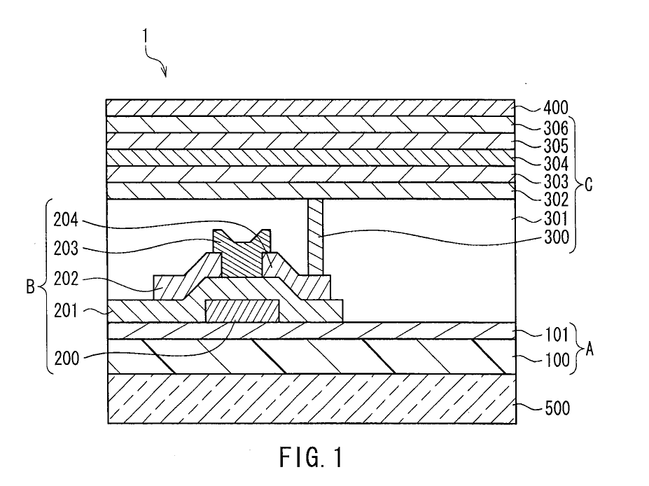

FIG. 1 is a schematic cross-sectional view showing an organic EL element 1 according to one embodiment. The organic EL element 1 includes a thin film transistor B formed on a substrate A and an organic EL layer C. Note that the organic EL element 1 is entirely covered with a sealing member 400. The organic EL element 1 may be separate from a base 500 or may include the base 500. Hereinafter, each component will be described in detail.

1. Substrate A

The substrate A includes a transparent resin substrate 100 and a gas barrier layer 101 formed on top of the transparent resin substrate 100. Here, the transparent resin substrate 100 is the polyamide film according to the present disclosure.

The transparent resin substrate 100 may have been annealed by heat. Annealing is effective in, for example, removing distortions and in improving the size stability against environmental changes.

The gas barrier layer 101 is a thin film made of SiOx, SiNx or the like, and is formed by a vacuum deposition method such as sputtering, CVD, vacuum deposition or the like. Generally, the gas barrier layer 101 has a thickness of, but is not limited to, about 10 nm to 100 nm. Here, the gas barrier layer 101 may be formed on the side of the transparent resin substrate 100 facing the gas barrier layer 101 in FIG. 1 or may be formed on the both sides of the transparent resin substrate 100.

2. Thin Film Transistor

The thin film transistor B includes a gate electrode 200, a gate insulating layer 201, a source electrode 202, an active layer 203, and a drain electrode 204. The thin film transistor B is formed on the gas barrier layer 101.

The gate electrode 200, the source electrode 202, and the drain electrode 204 are transparent thin films made of indium tin oxide (ITO), indium zinc oxide (IZO), zinc oxide (ZnO), or the like. For example, sputtering, vapor deposition, ion platting or the like may be use to form these transparent thin films. Generally, these electrodes have a film thickness of, but is not limited to, about 50 nm to 200 nm.

The gate insulating film 201 is a transparent insulating thin film made of SiO₂, Al₂O₃ or the like, and is formed by sputtering, CVD, vacuum deposition, ion plating or the like. Generally, the gate insulating film 201 has a film thickness of, but is not limited to, about 10 nm to 1 μm.

The active layer 203 is a layer of, for example, single crystal silicon, low temperature polysilicon, amorphous silicon, or oxide semiconductor, and a material best suited to the active layer 203 is used as appropriate. The active layer is formed by sputtering or the like.

3. Organic EL Layer

The organic EL layer C includes a conductive connector 300, an insulative flattened layer 301, a lower electrode 302 as the anode of the organic EL element A, a hole transport layer 303, a light-emitting layer 304, an electron transport layer 305, and an upper electrode 306 as the cathode of the organic EL element A. The organic EL layer C is formed at least on the gas barrier layer 101 or on the thin film transistor B, and the lower electrode 302 and the drain electrode 204 of the thin film transistor B are connected to each other electrically through the connector 300. Instead, the lower electrode 302 of the thin film transistor B and the source electrode 202 may be connected to each other through the connector 300.

The lower electrode 302 is the anode of the organic EL element 1a, and is a transparent thin film made of indium tin oxide (ITO), indium zinc oxide (IZO), zinc oxide (ZnO) or the like. ITO is preferred because, for example, high transparency, and high conductivity can be achieved.

For the hole transport layer 303, the light-emitting layer 304, and the electron transport layer 305, conventionally-known materials for organic EL elements can be used as is.

The upper electrode 306 is a film composed of a layer of lithium fluoride (LiF) having a film thickness of 5 nm to 20 nm and a layer of aluminum (Al) having a film thickness of 50 nm to 200 nm. For example, vapor deposition may be use to form the film.

When producing a bottom emission type organic EL element, the upper electrode 306 of the organic EL element 1a may be configured to have optical reflectivity. Thereby, the upper electrode 306 can reflect in the display side direction light generated by the organic EL element A and traveled toward the upper side as the opposite direction to the display side. Since the reflected light is also utilized for a display purpose, the emission efficiency of the organic EL element can be improved.

[Method of Producing Display Element, Optical Element, or Illumination Element]

Another aspect of the present disclosure relates to a method of producing a display element, an optical element, or an illumination element. In one or more embodiments, the production method according to the present disclosure is a method of producing the display element, the optical element, or the illumination element according to the present disclosure. Further, in one or more embodiments, the production method according to the present disclosure is a method of producing a display element, an optical element, or an illumination element, which includes the steps of: applying the polyamide resin composition according to the present disclosure onto a base; forming a polyamide film after the application step; and forming the display element, the optical element, or the illumination element on the side of the base not in contact with the polyamide resin film. The production method according to the present disclosure may further include the step of de-bonding, from the base, the display element, the optical element, or the illumination element formed on the base.

<Non-limiting Embodiment of Method of Producing Organic EL Element>

As one embodiment of the method of producing a display element according to the present disclosure, hereinafter, one embodiment of a method of producing an organic EL element will be described with reference to the drawing.

A method of producing the organic EL element 1 shown in FIG. 1 includes a fixing step, a gas barrier layer preparation step, a thin film transistor preparation step, an organic EL layer preparation step, a sealing step and a de-bonding step. Hereinafter, each step will be described in detail.

1. Fixing Step

In the fixing step, the transparent resin substrate 100 is fixed onto the base 500. Away to fix the transparent resin substrate 100 to the base 500 is not particularly limited. For example, an adhesive may be applied between the base 500 and the transparent substrate or a part of the transparent resin substrate 100 may be fused and attached to the base 500 to fix the transparent resin substrate 100 to the base 500. Further, as the material of the base, glass, metal, silicon, resin or the like is used, for example. These materials may be used alone or in combination of two or more as appropriate. Furthermore, the transparent resin substrate 100 may be attached to the base 500 by applying a releasing agent or the like to the base 500 and placing the transparent resin substrate 100 on the applied releasing agent. In one or more embodiments, the polyamide film 100 is formed by applying the polyamide resin composition according to the present disclosure to the base 500, and drying the applied polyamide resin composition.

2. Gas Barrier Layer Preparation Step

In the gas barrier layer preparation step, the gas barrier layer 101 is prepared on the transparent resin substrate 100. A way to prepare the gas barrier layer 101 is not particularly limited, and a known method can be used.

3. Thin Film Transistor Preparation Step

In the thin film transistor preparation step, the thin film transistor B is prepared on the gas barrier layer. Away to prepare the thin film transistor B is not particularly limited, and a known method can be used.

4. Organic EL Layer Preparation Step

The organic EL layer preparation step includes a first step and a second step. In the first step, the flattened layer 301 is formed. The flattened layer 301 can be formed by, for example, spin-coating, slit-coating, or ink-jetting a photosensitive transparent resin. At that time, an opening needs to be formed in the flattened layer 301 so that the connector 300 can be formed in the second step. Generally, the flattened layer has a film thickness of, but is not limited to, about 100 nm to 2 μm.

In the second step, first, the connector 300 and the lower electrode 302 are formed at the same time. Sputtering, vapor deposition, ion platting or the like may be used to form the connector 300 and the lower electrode 302. Generally, these electrodes have a film thickness of, but is not limited to, about 50 nm to 200 nm. Subsequently, the hole transport layer 303, the light-emitting layer 304, the electron transport layer 305, and the upper electrode 306 as the cathode of the organic EL element A are formed. To form these components, a method such as vapor deposition, application, or the like can be used as appropriate in accordance with the materials to be used and the laminate structure. Further, irrespective of the explanations given in this example, other layers may be chosen from known organic layers such as a hole injection layer, an electron transport layer, a hole blocking layer and an electron blocking layer as needed and be used to configuring the organic layers of the organic EL element A.

5. Sealing Step

In the sealing step, the organic EL layer A is sealed with the sealing member 400 from top of the upper electrode 306. For example, a glass material, a resin material, a ceramics material, a metal material, a metal compound or a composite thereof can be used to form the sealing member 400, and a material best suited to the sealing member 400 can be chosen as appropriate.

6. De-Bonding Step

In the de-bonding step, the organic EL element 1 prepared is stripped from the base 500. To implement the de-bonding step, for example, the organic EL element 1 may be physically stripped from the base 500. At that time, the base 500 may be provided with a de-bonding layer, or a wire may be inserted between the base 500 and the display element to remove the organic EL element. Further, examples of other methods of de-bonding the organic EL element 1 from the base 500 include the following: forming a de-bonding layer on the base 500 except at ends, and cutting, after the preparation of the element, the inner part from the ends to remove the element from the base; providing a layer of silicon or the like between the base 500 and the element, and irradiating the silicon layer with a laser to strip the element; applying heat to the base 500 to separate the base 500 and the transparent substrate from each other; and removing the base 500 using a solvent. These methods may be used alone or any of these methods may be used in combination of two or more. Especially in one or more embodiments, the strength of adhesion between PA film and the Base can be controlled by silane coupling agent, so that the organic EL element 1 may be physically stripped without using the complicated process such as described above.

In one or more embodiments, the organic EL element obtained by the method of producing a display, optical or illumination element according to the present embodiment has excellent characteristics such as excellent transparency and heat-resistance, low linear expansivity and low optical anisotropy.

[Display Device, Optical Device, and Illumination Device]

Another aspect of the present disclosure relates to a display device, an optical device, or an illumination device using the display element, the optical element, or the illumination element according to the present disclosure, or a method of producing the display device, the optical device, or the illumination device. Examples of the display device include, but are not limited to, an imaging element, examples of the optical device include, but are not limited to, a photoelectric complex circuit, and examples of the illumination device include, but are not limited to, a TFT-LCD and OEL illumination.

This disclosure may relate to one or plurality of the following embodiments.

<1> A solution of polyamide comprising: an aromatic polyamide; and an amphiphilic solvent.

<2> The solution of polyamide according to <1>, further comprising an aprotic solvent.

<3> The solution according to <1> or <2>, wherein the amphiphilic solvent is composed of a hydrocarbon group, and a hydroxyl group and/or an ether linkage.

<4> The solution according to any one of <1> to <3>, wherein the amphiphilic solvent is selected from the group consisting of butyl cellosolve (BCS), methyl cellosolve, ethyl cellosolve, propylene glycol monobutylether, diethyleneglycol monobutylether, and a combination thereof.

<5> The solution according to any one of <1> to <4>, wherein the aprotic solvent has a nitrogen atom.

<6> The solution according to any one of <1> to <5>, wherein the aprotic solvent is selected from the group consisting of N,N-dimethylacetamide (DMAc), DMSO, N-methyl-2-pyrrolidinone (NMP), N-dimethylformamide (DMF), and a combination thereof.

<7> The solution according to any one of <1> to <6>, wherein a ratio of the amount of aromatic diamine monomer components that have an arylene group other than para bond to the total amount of diamine monomer components used for synthesis of the polyamide is 15 mol % or more, or, wherein a ratio of the amount of aromatic dicarboxylic acid dichloride monomer components that have an arylene group other than para bond to the total amount of dicarboxylic acid dichloride monomer components used for synthesis of the polyamide is 20 mol % or more.

<8> The solution according to any one of <1> to <7>, wherein the polyamide comprising:
an aromatic polyamide having repeat units of general formulas (I) and (II):

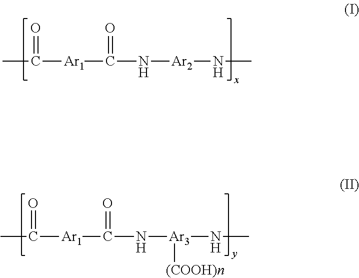

wherein x represents mole % of the repeat structure (I), y represents mole % of the repeat structure (II), x varies from 90 to 100, and y varies from 10 to 0;
wherein n=1 to 4;
wherein Ar₁ is selected from the group comprising:

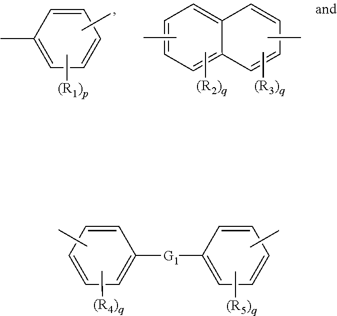

wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, or substituted aryl such as halogenated aryls, alkyl ester and substituted alkyl esters, and combinations thereof, wherein G₁ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is an aryl group or substituted aryl group, such as phenyl group, biphenyl group, perfluorobiphenyl group, 9,9-bisphenylfluorene group, and substituted 9,9-bisphenylfluorene;
wherein Ar₂ is selected from the group of comprising:

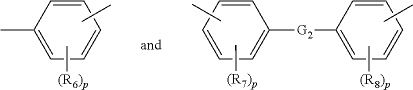

wherein p=4, wherein R₆, R₇, R₈ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof, wherein G₂ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is an aryl group or substituted aryl group, such as phenyl group, biphenyl group, perfluorobiphenyl group, 9,9-bisphenylfluorene group, and substituted 9,9-bisphenylfluorene;
wherein Ar₃ is selected from the group comprising:

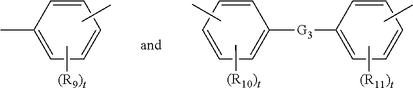

wherein t=1 to 3, wherein R₉, R₁₀, R₁₁ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof, wherein G₃ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is an aryl group or substituted aryl group, such as phenyl group, biphenyl group, perfluorobiphenyl group, 9,9-bisphenylfluorene group, and substituted 9,9-bisphenylfluorene.

<9> The solution according to <8>, wherein the polyamide contains multiple repeat units of the general formulas (I) and (II), and wherein Ar₁, Ar₂, and Ar₃ are the same or different.

<10> The solution according to any one of <1> to <9>, wherein the polyamide is obtained by polymerizing aromatic dicarboxylic acid dichlorides as shown in the following general structures:

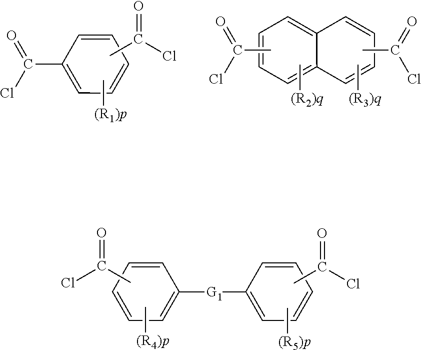

wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as a halogenated alkoxy, aryl, or substituted aryl such as halogenated aryls, alkyl ester and substituted alkyl esters, and combinations thereof. It is to be understood that each R₁ can be different, each R₂ can be different, each R₃ can be different, each R₄ can be different, and each R₅ can be different. G₁ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is an aryl group or substituted aryl group, such as phenyl group, biphenyl group, perfluorobiphenyl group, 9,9-bisphenylfluorene group, and substituted 9,9-bisphenylfluorene.

<11> The solution according to any one of <1> to <10>, wherein the polyamide is obtained by polymerizing aromatic diamines as shown in the following general structures:

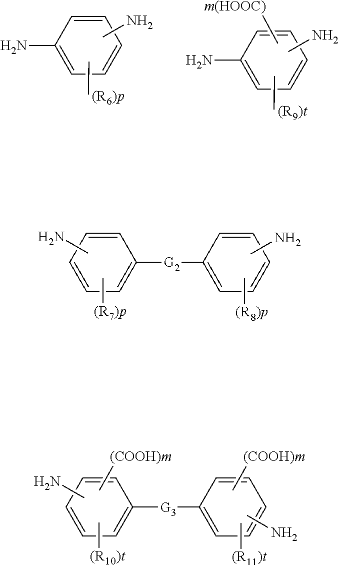

wherein p=4, m=1 or 2, and t=1 to 3, wherein R₆, R₇, R₈, R₉, R₁₀, R₁₁ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as a halogenated alkoxy, aryl, substituted aryl such as halogenated aryls, alkyl ester, and substituted alkyl esters, and combinations thereof. It is to be understood that each R₆ can be different, each R₇ can be different, each R₈ can be different, each R₉ can be different, each R₁₀ can be different, and each R₁₁ can be different. G₂ and G₃ are selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is an aryl group or substituted aryl group, such as phenyl group, biphenyl group, perfluorobiphenyl group, 9,9-bisphenylfluorene group, and substituted 9,9-bisphenylfluorene.

<12> The solution according to any one of <1> to <11>, wherein at least one of terminals of the polyamide is end-capped.

<13> The solution according to any one of <1> to <12>, for use in the process for manufacturing a display element, an optical element or an illumination element, comprising the steps of:
a) applying a solution of an aromatic polyamide onto a base;
b) forming a polyamide film on the base after the applying step (a); and
c) forming the display element, the optical element or the illumination element on the surface of polyamide film,
wherein the base or the surface of the base is composed of glass or silicon wafer.

<14> A laminated composite material, comprising a glass plate, and a polyamide resin layer;
wherein the polyamide resin layer is laminated onto one surface of the glass plate; and
wherein the polyamide resin layer is obtained by applying the solution of polyamide according to any one of <1> to <13> onto the glass plate.
   <15> The laminated composite material according to <14>, wherein the polyamide resin is obtained by a process comprising a step of heating the polyamide resin at 330° C. or more.
   <16> The laminated composite material according to <14> or <15>, wherein the thickness of the glass plate is 0.3 mm or more.
   <17> The laminated composite material according to any one of <14> to <16>, wherein the thickness of the polyamide resin is 500 μm or less.
   <18> The laminated composite material according to any one of <14> to <17>, wherein the total light transmittance of the polyamide resin at 550 nm is 70% or more.
   <19> A process for manufacturing a display element, an optical element or an illumination element, comprising the steps of:
forming the display element, the optical element or the illumination element on a surface of the polyamide resin layer of the laminated composite material according to any one of <14> to <18>, wherein the surface is not opposed to the glass plate.
   <20> The process according to <19>, further comprising the step of
de-bonding, from the glass plate, the display element, the optical element or the illumination element formed on the base.

<21> A display element, an optical element or an illumination element manufactured using the solution of polyamide according to any one of <1> to <13> or the laminated composite material according to any one of <14> to <18>, comprising the polyamide resin of the laminated composite material.

### EXAMPLES

### Preparation of Solution of Polyamide

Polyamide solutions (Solutions 1 to 9) were prepared using components as described in Table 1 as well as bellow. The number-average molecular weight (Mn), the weight-average molecular weight (Mw) and the viscosity of each solution of polyamide prepared were determined in the following manners.

### [Aromatic Diamine]

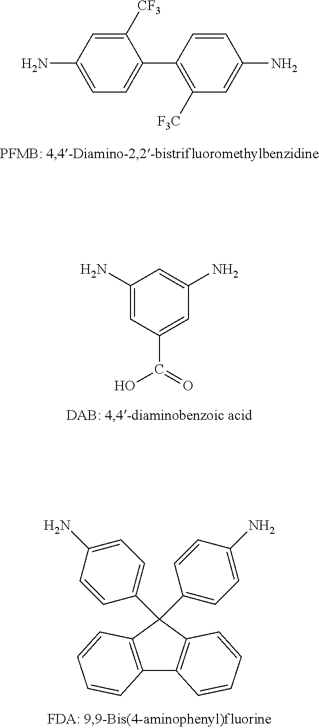 [SMILES: Nc1ccc(-c2ccc(N)cc2C(F)(F)F)c(C(F)(F)F)c1 ; Nc1cc(N)cc(C(=O)O)c1 ; Nc1ccc(C2(c3ccc(N)cc3)c3ccccc3-c3ccccc32)cc1]

### [Solvent]

BCS: butyl cellosolve (amphiphilic solvent)
DMAc: N,N-dimethylacetamide (aprotic solvent)

### [Aromatic Diacid Dichloride]

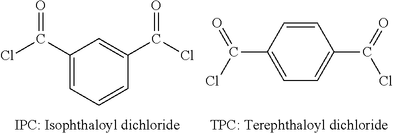

### [Trapping Reagent]

PrO: propylene oxide

[Number-Average Molecular Weight (Mn) and Weight-Average Molecular Weight (Mw)]

The number-average molecular weight (Mn) and the weight-average molecular weight (Mw) of each synthesized polyamide were measured using the following device and mobile phase.

Device: Gel Permeation Chromatography (HLC-8320 GPC from Tosoh Corporation)
Mobile Phase: DMAc, lithium bromide 10 mM, phosphoric acid 5 mM

This example illustrates the general procedure for the preparation of Solution 1 containing 5 weight % of a copolymer of TPC, IPC, DAB, and PFMB (75%/25%/5%/95% mol ratio) in a mixed solvent of BCS/DMAc (50/50, weigh ratio).

To a 250 ml three necked round bottom flask, equipped with a mechanical stirrer, a nitrogen inlet and outlet, are added PFMB (3.042 g, 0.0095 mol), DAB (0.0761 g, 0.0005 mol) DMAc (21 ml). After the PFMB dissolved completely, PrO (1.4 g, 0.024 mol) was added to the solution. The solution is cooled to 0° C. Under stirring, IPC (1.0049 g, 0.00495 mol) was added to the solution, and the flask wall was washed with DMAc (1.5 ml). After 15 minutes, TPC (1.0049 g, 0.00495 mol) was added to the solution and the flask wall was again washed with DMAc (1.5 ml). After two hours, benzoyl chloride (0.030 g, 0.216 mmol) was added to the solution, and stirred for another two hours adding BCS (24 ml), to obtain Solution 1.

Solutions 2 to 9 were also prepared in the same manner as Solution 1. Note that the amount of TPC finally added to Solution 2 was somewhat smaller than that added to Solution 3 so as to reduce the number-average molecular weight of Solution 2.

[Whitening Test]

Solutions 1 to 9 prepared were each applied onto a 10 cm×10 cm glass (EAGLE XG (Corning Inc., U.S.A.) by spin-coating so that a coating with a thickness of about 20 μm was formed, and each coating was observed visually at a temperature of 23° C. and a relative humidity of 60% to measure the time for each coating to become white. Table 1 below provides the results. It should be noted that the test environment is not necessarily limited to the above. For example, IEC-Publication 160-1963 defines that the recommended temperature and relative humidity ranges for conducting the measurement are 15 to 35° C. and 45 to 75%, respectively. The ranges used in Examples were determined within the ranges defined by IEC-Publication 160-1963. In Examples, the whitening was observed visually in Examples. Specifically, the whitening refers to one that negatively affects the display quality of a display element, an optical element, or an illumination element.

TABLE 1

| | | | | Number | | Whitening | | | |
|---|---|---|---|---|---|---|---|---|---|
| | Components | | | average | | (checked | Percentage of | | |
| | | | Diacid | molecular | Molecular | through visual | flexible component | | |
| | | | Dichloride | weight | weight | inspection) | Diamine | Diacid | vs |
| | Diamine | Solvent | (molar | Mn × | distribution | 23° C., 60% RH | vs | vs | total |
| Table 1 | ratio) | (weight ratio) | ratio) | 10\hat{ }4 | Mw/Mn | (Clean room) | Diamine | Diacid | monomer |
| Solution 1 | PFMB/DAB | DMAc/BCS | IPC/TPC | 8.4 | 3.05 | 6 h | 5% | 25% | 15.0% |
| | (95/5) | (50/50) | (25/75) | | | | | | |
| Solution 2 | PFMB/DAB | DMAc/BCS | IPC/TPC | 6.9 | 2.92 | 6 h | 5% | 30% | 17.5% |
| | (95/5) | (50/50) | (30/70) | | | | | | |
| Solution 3 | PFMB/DAB | DMAc/BCS | IPC/TPC | 8.6 | 2.51 | >24 h | 5% | 30% | 17.5% |
| | (95/5) | (50/50) | (30/70) | | | | | | |
| Solution 4 | PFMB/DAB | DMAc/BCS | IPC/IPC | 9.3 | 2.72 | >24 h | 5% | 50% | 27.5% |
| | (95/5) | (50/50) | (50/50) | | | | | | |
| Solution 5 | PFMB/DAB | DMAc/BCS | IPC/TPC | 7.7 | 2.02 | >24 h | 5% | 90% | 47.5% |
| | (95/5) | (50/50) | (90/10) | | | | | | |
| Solution 6 | PFMB/DAB/FDA | DMAc/BCS | TPC | 6.3 | 4.02 | 6 h | 20% | 0 | 10.0% |
| | (85/5/15) | (50/50) | | | | | | | |
| Solution 7 | PFMB/DAB/FDA | DMAc/BCS | TPC | 7.0 | 4.46 | >24 h | 35% | 0 | 17.5% |
| | (65/5/30) | (50/50) | | | | | | | |
| Solution 8 | PFMB/DAB | DMAc | IPC/TPC | 8.4 | 3.05 | <10 min | 5% | 25% | 15.0% |
| | (95/5) | | (25/75) | | | | | | |
| Solution 9 | PFMB/DAB | DMAc | IPC/TPC | 6.9 | 2.92 | <10 min | 5% | 30% | 17.5% |
| | (95/5) | | (30/70) | | | | | | |

As can be seen from Table 1, for Solutions 1 to 7 using BCS as a solvent, their whitening was suppressed significantly in comparison with Solutions 8 and 9. Furthermore, for Solutions 3 to 5 and 7 having a high proportion of flexible monomer component and high molecular weight (or small molecular weight distribution), their whitening was suppressed more noticeably in comparison with Solutions 1, 2 and 6.

The embodiments have been described, hereinabove. It will be apparent to those skilled in the art that the above methods and apparatuses may incorporate changes and modifications without departing from the general scope of this disclosure. It is intended to include all such modifications and alterations insofar as they come within the scope of the appended claims or the equivalents thereof. Although the description above contains much specificity, this should not be construed as limiting the scope of the disclosure, but as merely providing illustrations of some of the embodiments of this disclosure. Various other embodiments and ramifications are possible within its scope.

Furthermore, notwithstanding that the numerical ranges and parameters setting forth the broad scope of the disclosure are approximations, the numerical values set forth in the specific examples are reported as precisely as possible. Any numerical value, however, inherently contain certain errors necessarily resulting from the standard deviation found in their respective testing measurements.

What is claimed is:

1. A solution of polyamide comprising:
an aromatic polyamide; and
an amphiphilic solvent.

2. The solution of polyamide according to claim 1, further comprising an aprotic solvent.

3. The solution according to claim 1, wherein the amphiphilic solvent is composed of a hydrocarbon group, and a hydroxyl group and/or an ether linkage.

4. The solution according to claim 1, wherein the amphiphilic solvent is selected from the group consisting of butyl cellosolve (BCS), methyl cellosolve, ethyl cellosolve, propylene glycol monobutylether, diethyleneglycol monobutylether, and a combination thereof.

5. The solution according to claim 1, wherein the aprotic solvent has a nitrogen atom.

6. The solution according to claim 1, wherein the aprotic solvent is selected from the group consisting of N,N-dimethylacetamide (DMAc), DMSO, N-methyl-2-pyrrolidinone (NMP), N-dimethylformamide (DMF), and a combination thereof.

7. The solution according to claim 1, wherein a ratio of the amount of aromatic diamine monomer components that have an arylene group other than para bond to the total amount of diamine monomer components used for synthesis of the polyamide is 15 mol % or more, or, wherein a ratio of the amount of aromatic dicarboxylic acid dichloride monomer components that have an arylene group other than para bond to the total amount of dicarboxylic acid dichloride monomer components used for synthesis of the polyamide is 20 mol % or more.

8. The solution according to claim 1, wherein the polyamide comprising:
an aromatic polyamide having repeat units of general formulas (I) and (II): 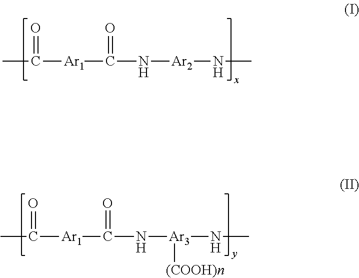
wherein x represents mole % of the repeat structure (I), y represents mole % of the repeat structure (II), x varies from 90 to 100, and y varies from 10 to 0;
wherein n=1 to 4;
wherein Ar₁ is selected from the group comprising: 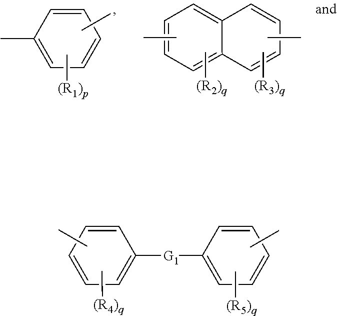
wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, or substituted aryl such as halogenated aryls, alkyl ester and substituted alkyl esters, and combinations thereof, wherein G₁ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is an aryl group or substituted aryl group, such as phenyl group, biphenyl group, perfluorobiphenyl group, 9,9-bisphenylfluorene group, and substituted 9,9-bisphenylfluorene;
wherein Ar₂ is selected from the group of comprising: 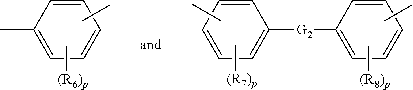
wherein p=4, wherein R₆, R₇, R₈ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof, wherein G₂ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is an aryl group or substituted aryl group, such as phenyl group, biphenyl group, perfluorobiphenyl group, 9,9-bisphenylfluorene group, and substituted 9,9-bisphenylfluorene;
wherein Ar₃ is selected from the group comprising: 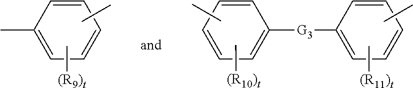
wherein t=1 to 3, wherein R₉, R₁₀, R₁₁ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof, wherein G₃ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is an aryl group or substituted aryl group, such as phenyl group, biphenyl group, perfluorobiphenyl group, 9,9-bisphenylfluorene group, and substituted 9,9-bisphenylfluorene.

9. The solution according to claim 8, wherein the polyamide contains multiple repeat units of the general formulas (I) and (II), and wherein Ar₁, Ar₂, and Ar₃ are the same or different.

10. The solution according to claim 1, wherein the polyamide is obtained by polymerizing aromatic dicarboxylic acid dichlorides as shown in the following general structures: 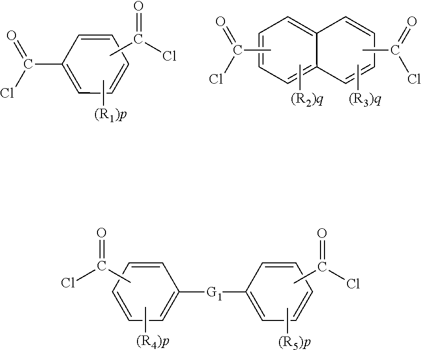
wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as a halogenated alkoxy, aryl, or substituted aryl such as halogenated aryls, alkyl ester and substituted alkyl esters, and combinations thereof. It is to be understood that each R₁ can be different, each R₂ can be different, each R₃ can be different, each R₄ can be different, and each R₅ can be different. G₁ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is an aryl group or substituted aryl group, such as phenyl group, biphenyl group, perfluorobiphenyl group, 9,9-bisphenylfluorene group, and substituted 9,9-bisphenylfluorene.

11. The solution according to claim 1, wherein the polyamide is obtained by polymerizing aromatic diamines as shown in the following general structures: 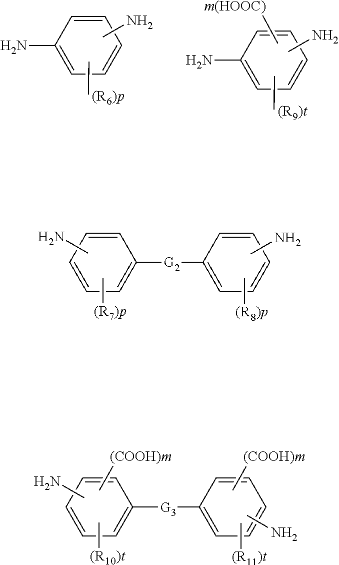
wherein p=4, m=1 or 2, and t=1 to 3, wherein R₆, R₇, R₈, R₉, R₁₀, R₁₁ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as a halogenated alkoxy, aryl, substituted aryl such as halogenated aryls, alkyl ester, and substituted alkyl esters, and combinations thereof. It is to be understood that each R₆ can be different, each R₇ can be different, each R₈ can be different, each R₉ can be different, each R₁₀ can be different, and each R₁₁ can be different. G₂ and G₃ are selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is an aryl group or substituted aryl group, such as phenyl group, biphenyl group, perfluorobiphenyl group, 9,9-bisphenylfluorene group, and substituted 9,9-bisphenylfluorene.

12. The solution according to claim 1, wherein at least one of terminals of the polyamide is end-capped.

13. The solution according to claim 1, for use in the process for manufacturing a display element, an optical element or an illumination element, comprising the steps of:
a) applying a solution of an aromatic polyamide onto a base;
b) forming a polyamide film on the base after the applying step (a); and
c) forming the display element, the optical element or the illumination element on the surface of polyamide film,
wherein the base or the surface of the base is composed of glass or silicon wafer.

14. A laminated composite material, comprising a glass plate, and a polyamide resin layer;
wherein the polyamide resin layer is laminated onto one surface of the glass plate; and
wherein the polyamide resin layer is obtained by applying the solution of polyamide according to claim 1 onto the glass plate.

15. The laminated composite material according to claim 14, wherein the polyamide resin is obtained by a process comprising a step of heating the polyamide resin at 330° C. or more.

16. The laminated composite material according to claim 14, wherein the thickness of the glass plate is 0.3 mm or more.

17. The laminated composite material according to claim 14, wherein the thickness of the polyamide resin is 500 μm or less.

18. The laminated composite material according to claim 14, wherein the total light transmittance of the polyamide resin at 550 nm is 70% or more.

19. A process for manufacturing a display element, an optical element or an illumination element, comprising the steps of:
forming the display element, the optical element or the illumination element on a surface of the polyamide resin layer of the laminated composite material according to claim 14, wherein the surface is not opposed to the glass plate.

20. The process according to claim 19, further comprising the step of:
de-bonding, from the glass plate, the display element, the optical element or the illumination element formed on the base.
